(19) United States
(12) Patent Application Publication
(10) Pub. No.: US 2011/0111539 A1
(43) Pub. Date: May 12, 2011

(54) METHOD OF MANUFACTURING LIGHT EMITTING DIODE PACKAGE

(75) Inventors: Chieh-Lung Lai, Hsinchu City (TW); Jian-Shian Lin, Yilan County (TW); Hsiu-Jen Lin, Taipei County (TW)

(73) Assignee: INDUSTRIAL TECHNOLOGY RESEARCH INSTITUTE, Hsinchu (TW)

(21) Appl. No.: 12/846,839

(22) Filed: Jul. 30, 2010

(30) Foreign Application Priority Data
Nov. 12, 2009 (TW) 98138510

(51) Int. Cl. H01L 33/60; H01L 33/64; H01L 33/62

(52) U.S. Cl. 438/27; 257/E33.056; 257/E33.066; 257/E33.067; 257/E33.075

(57) ABSTRACT

A method of manufacturing a light emitting diode (LED) package includes disposing at least one LED chip on a first surface of a lead frame, and the LED chip is connected to the lead frame. At least one heat dissipation area corresponding to the LED chip is defined on a second surface of the lead frame. A thermal conductive material is disposed in the heat dissipation area. The thermal conductive material directly comes into contact with the lead frame. A solidification process is performed to solidify the thermal conductive material and form a plurality of heat dissipation blocks. The heat dissipation blocks directly come into contact with the lead frame, and the solidification process is performed at a temperature substantially lower than 300° C.

### CROSS-REFERENCE TO RELATED APPLICATION

This application claims the priority benefit of Taiwan application serial no. 98138510, filed on Nov. 12, 2009. The entirety of the above-mentioned patent application is hereby incorporated by reference herein and made a part of this specification.

### BACKGROUND OF THE INVENTION

1. Field of the Invention

The disclosure relates to a method of manufacturing a light emitting diode (LED) package and particularly relates to a method of manufacturing an LED package having heat dissipation blocks.

2. Description of Related Art

LED is a semiconductor element, and a material of an LED chip of the LED mainly includes group III-V chemical elements, such as gallium phosphide (GaP), gallium arsenide (GaAs), and other compound semiconductors. The light emitting principle of the LED chip lies in conversion of electric energy into light. Namely, current is applied to the compound semiconductor, so that energy is released in a form of light when electrons and electron holes are combined, thus achieving a light emitting effect. Since the light emitting phenomenon of the LED does not result from heating or electricity discharge, the lifespan of the LED reaches 100,000 hours or more, and idling time is not required. Moreover, the LED has the characteristics of fast response speed (about 10⁻⁹ seconds), compact size, low power consumption, low pollution, high reliability, capability of mass production, and so forth. Therefore, the application of LED is fairly extensive, for example, mega-size outdoor display boards, traffic lights, mobile phones, light sources of scanners and facsimile machine, illumination devices, and so on.

In recent years, as the brightness and light emitting efficiency of LEDs have been improved, and the mass production of white light LEDs is carried out successfully, the white light LEDs have been applied to the illumination devices including indoor lightening devices, outdoor streetlamps, etc. In general, LEDs all encounter heat dissipation problem. When an LED is operated at overly high temperature, brightness of the LED lamp is reduced, and the lifespan of the LED is shortened. Accordingly, how to equip the LED lamp with a proper heat dissipation system has drawn attention of researchers and designers in this field.

At present, heat dissipation components (e.g. heat dissipation copper blocks) in fixed shape are disposed in the LED package in order to prevent temperature raise at junctions of the LEDs. However, due to the heat dissipation copper blocks, the packaging process becomes more complicated.

### SUMMARY OF THE INVENTION

A method of manufacturing an LED package is introduced herein to form heat dissipation blocks of the LED package in a simple way.

In a method of manufacturing an LED package of the disclosure, at least one LED chip is disposed on a first surface of a lead frame, and the LED chip is connected to the lead frame. At least a heat dissipation area is defined on a second surface of the lead frame, and the second surface is opposite to the first surface. The heat dissipation area corresponds to the LED chip. A thermal conductive material is disposed in the heat dissipation area. The thermal conductive material directly comes into contact with the lead frame, and a thermal conductive coefficient of the thermal conductive material is substantially greater than 10 W/m-K. A solidification process is performed to solidify the thermal conductive material and form at least one heat dissipation block. The heat dissipation block directly comes into contact with the lead frame.

According to an exemplary embodiment, a method of disposing the thermal conductive material in the heat dissipation area includes placing a fixture on the second surface of the lead frame. The fixture has a plurality of holes exposing the heat dissipation area. The holes are filled with the thermal conductive material. After the solidification process is performed, the method of manufacturing the LED package further includes removing the fixture to form the heat dissipation block.

According to an exemplary embodiment, before the thermal conductive material is disposed in the heat dissipation area, the LED chip and the lead frame can be packaged into a package housing, and the package housing has a plurality of holes exposing the heat dissipation area on the lead frame. According to an exemplary embodiment, a method of disposing the thermal conductive material in the heat dissipation area includes directly disposing the thermal conductive material in the holes of the package housing, for example.

According to an exemplary embodiment, a method of disposing the thermal conductive material in the heat dissipation area includes screen printing the thermal conductive material into the heat dissipation area.

According to an exemplary embodiment, the method of manufacturing the LED package further includes packaging the LED chip and the lead frame into a package housing after the heat dissipation block is formed, and the package housing exposes a side of the heat dissipation block away from the lead frame.

According to an exemplary embodiment, the method of manufacturing the LED package further includes performing a wire bonding process to electrically connect the LED chip to the lead frame.

According to an exemplary embodiment, the thermal conductive material includes solder paste, solder bar, silver adhesive, metal powder, or liquid metal.

According to an exemplary embodiment, the method of manufacturing the LED package further includes performing a punching process before the thermal conductive material is disposed in the heat dissipation area, such that the lead frame is a three-dimensional lead frame.

According to an exemplary embodiment, the method of manufacturing the LED package further includes connecting the lead frame to a heat dissipation substrate through the heat dissipation block. According to an exemplary embodiment, the heat dissipation block and the heat dissipation substrate are connected by performing a reflow process.

According to an exemplary embodiment, the method of manufacturing the LED package further includes packaging the LED chip into at least one reflective cup when the LED chip is disposed on the first surface of the lead frame.

According to an exemplary embodiment, the thermal conductive material directly comes into contact with the lead frame, and a thermal conductive coefficient of the thermal conductive material is substantially greater than 10 W/m-K.

According to an exemplary embodiment, the solidification process includes performing a cooling process to solidify the thermal conductive material and form the heat dissipation block. According to an exemplary embodiment, the solidification process further includes performing a heating process before performing the cooling process to fluidity the thermal conductive material and solidifying the thermal conductive material and forming the heat dissipation block in the cooling process.

Based on the above, the heat dissipation block in this disclosure is formed on the back side of the lead frame when the solidification process is performed at a low temperature. Thereby, the LED package can have proper heat dissipation design, and the process of manufacturing the heat dissipation block is rather simple. On the other hand, heat dissipation blocks in different shapes can be formed during the solidification process according to the disclosure, such that the design of the LED package is rather flexible.

Several exemplary embodiments accompanied with figures are described in detail to further describe the disclosure.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1A to FIG. 1D are schematic views illustrating a method of manufacturing an LED package according to an exemplary embodiment.

FIG. 2 is a schematic view illustrating a method of manufacturing an LED package according to another exemplary embodiment.

FIG. 3A to FIG. 3D are schematic views illustrating a method of manufacturing an LED package according to yet another exemplary embodiment.

### DESCRIPTION OF EMBODIMENTS

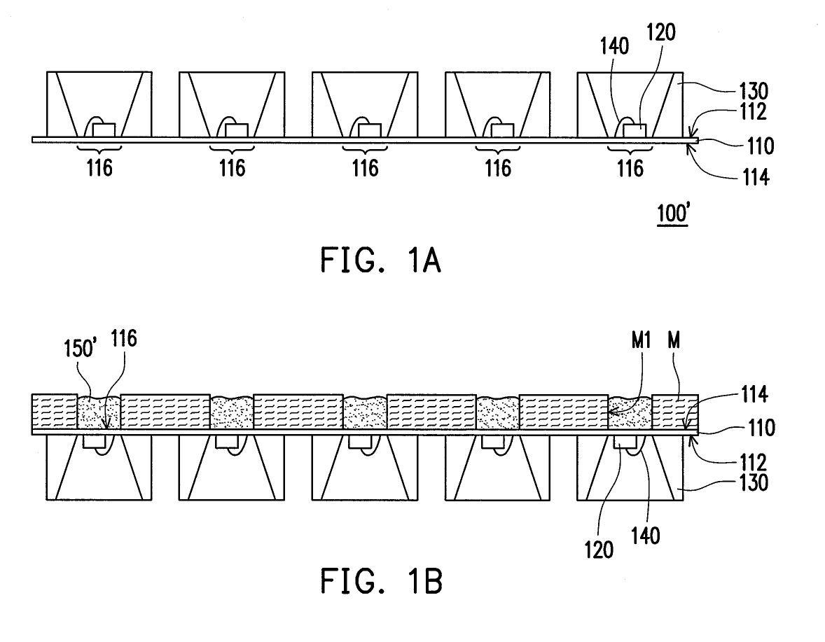

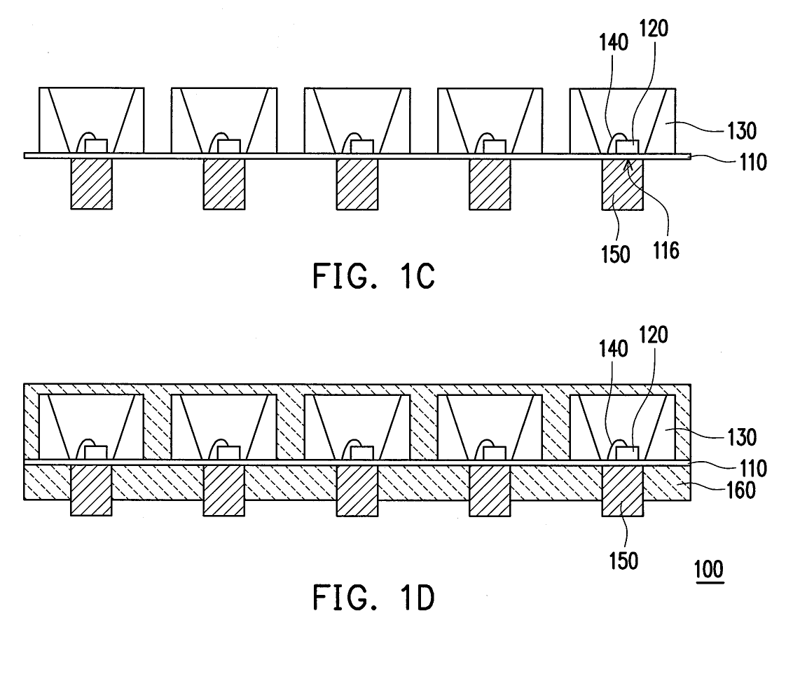

FIG. 1A to FIG. 1D are schematic views illustrating a method of manufacturing an LED package according to an exemplary embodiment. As indicated in FIG. 1A, a plurality of LED chips 120 are disposed on a first surface 112 of a lead frame 110, and the LED chips 120 are disposed in a plurality of reflective cups 130. The LED chips 120 are electrically connected to the lead frame 110 to form a semi-finished LED package 100′. It should be mentioned that a plurality of heat dissipation areas 116 are defined on a second surface 114 of the lead frame 110, and the second surface 114 is opposite to the first surface 112. The heat dissipation areas 116 correspond to the LED chips 120. Besides, the lead frame 110 in the heat dissipation areas 116 is exposed and is not covered by any element.

In the exemplary embodiment, the reflective cups 130 are formed by performing an injection process. After the reflective cups 130 are formed, the LED chips 120 can be adhered to the lead frame 110 by silver adhesive or solder. The LED chips 120 can also be adhered to the lead frame 110 by eutectic bonding. On the other hand, the LED chips 120 can be electrically connected to the lead frame 110 by performing a wire bonding process, such that the LED chips 120 and the lead frame 110 are connected through conductive wires 140.

In FIG. 1B and FIG. 1C, a thermal conductive material 150′ is disposed in the heat dissipation areas 116, and a solidification process is performed to solidify the thermal conductive material 150′ to form a plurality of heat dissipation blocks 150. To elaborate the usage of a fixture M, components in FIG. 1A are horizontally turned upside down in FIG. 1B. Same reference numbers in FIG. 1A, FIG. 1B, and FIG. 1C represent the same components. The solidification process is performed at a temperature substantially lower than 300° C. In other embodiments, the temperature may lower than 180° C. As indicated in FIG. 1B, the thermal conductive material 150′ directly comes into contact with the lead frame 110, and a thermal conductive coefficient of the thermal conductive material 150′ is substantially greater than 10 W/m-K, so as to effectively dissipate heat.

Specifically, in FIG. 1B, a method of disposing the thermal conductive material 150′ in the heat dissipation areas 116 and the solidification process include following steps, for example. The fixture M is placed on the second surface 114 of the lead frame 110, and the fixture M has a plurality of holes M1 exposing the heat dissipation areas 116. The holes M1 are filled with the thermal conductive material 150′ and a subsequent heating process is performed. Besides, a cooling process is further performed after performing the heating process, so as to solidify the thermal conductive material 150′, and the fixture M is removed to form the heat dissipation blocks 150 depicted in FIG. 1C. To be more specific, the heating process is carried out to fluidify the thermal conductive material 150′, such that the holes M1 can be filled with the thermal conductive material 150′. By contrast, the cooling process is performed to solidify the fluid thermal conductive material 150′, so as to form the heat dissipation blocks 150 fitting the shape of the holes M1. Certainly, in other exemplary embodiments, the thermal conductive material 150′ can be liquid metal, i.e. metal that is heated and liquidized. Hence, the heat dissipation blocks 150 are formed by directly filling the holes M1 of the fixture M with the heated and liquidized metal, for example, and the cooling process is implemented to solidify the liquid metal and form the heat dissipation blocks 150. That is to say, the solidification process can either include the heating and the cooling processes or merely include the cooling process.

In general, overly high temperature in the manufacturing process gives rise to deterioration or degradation of the LED chips 120. Thereby, the LED chips have certain tolerance to temperature in the packaging process. For instance, the temperature at which the process of packaging some LED chips 120 can reach 350° C. for five seconds, while the temperature at which the process of packaging other LED chips 120 can reach 250° C. for ten seconds. Accordingly, after the LED chips 120 are disposed in the lead frame 110, any step in the manufacturing process is required not to be carried out at an excessively high temperature. The temperature at which the solidification process is performed is, for example, below 300° C. or even below 180° C. according to the exemplary embodiment, so as to prevent the LED chips 120 from being damaged by high temperature. The thermal conductive material 150′ applied in the manufacturing process basically has low melting point, e.g. lower than 300° C.

In particular, the thermal conductive material complying with said requirement is solder paste, solder bar, silver adhesive, metal powder, or liquid metal, for example. Here, a material of the metal powder or the liquid metal respectively includes tin, indium, or an alloy thereof. The Sn-58Bi solder paste having the melting point of approximately 140° C. at most can be applied in the solidification process of the exemplary embodiment. As a matter of fact, when the Sn-58Bi solder paste serves as the thermal conductive material 150′ of this exemplary embodiment, the solidification process includes performing the heating process at substantially 150° C.˜160° C. for approximately sixty seconds to melt the solder paste, for example. The melted solder paste is then cooled off and solidified, so as to form the heat dissipation blocks 150.

In this exemplary embodiment, the thermal conductive material 150′ is, for example, a fluid material or a powder material, and therefore the thermal conductive material 150′ can be injected into each of the heat dissipation areas 116, or each of the heat dissipation areas 116 can be coated by the thermal conductive material 150′. Conventionally, each of the heat dissipation blocks in fixed shape must be placed in one of the heat dissipation areas. By contrast, the manufacturing process of the heat dissipation blocks 150 is relatively easy according to the exemplary embodiment. As a result, the entire process can have improved efficiency when the method of manufacturing the LED package described in the exemplary embodiment is applied. Moreover, the shaped heat dissipation blocks 150 directly come into contact with the lead frame 110, which results in favorable thermal conductivity.

To elucidate the thermal conductivity that results from the shaped heat dissipation blocks 150 directly coming into contact with the lead frame 110, package structures with/without tin wires directly disposed at back sides of the LED chips 120 are inspected. When the LED chips 120 having no tin wire emit light for a period of time, heat of the package structure can merely be dissipated by the lead frame 110. Therefore, after the LED chips 120 emit light for a period of time at the room temperature of approximately 25° C. with the power supply of 0.85 W, the temperature of the heat dissipation areas 116 reaches approximately 78° C. By contrast, in the LED chips 120 having the tin wires that are disposed on the back sides and directly come into contact with the lead frame 110, after the LED chips 120 emit light for a period of time on the same condition, the temperature of the heat dissipation areas 116 reaches approximately 65.3° C. Accordingly, the heat dissipation blocks 150 directly coming into contact with the lead frame 110 indeed improve heat dissipation efficacy according to the exemplary embodiment.

With reference to FIG. 1D, the LED chips 120 and the lead frame 110 are packaged into a package housing 160 to form the LED package 100. In this exemplary embodiment, the package housing 160 exposes sides of the heat dissipation blocks 150 away from the lead frame 110, so as to improve the heat dissipation efficiency. In the LED package 100, a reflow process can be carried out to directly dispose the heat dissipation blocks 150 on a heat dissipation substrate (not shown), so as to enhance heat dissipation performance.

Note that the heat dissipation blocks 150 are formed at a relatively low temperature, which is thus unlikely to damage the LED chips 120. Thereby, the LED package 100 has favorable manufacturing yield and can be formed by performing a rather simple packaging process.

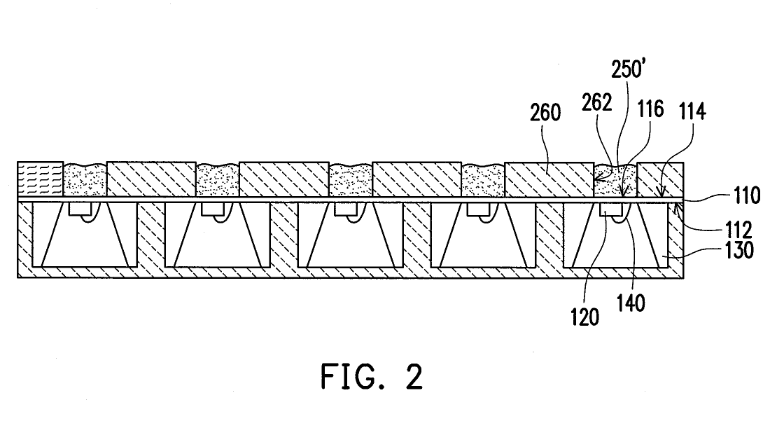

FIG. 2 is a schematic view illustrating a method of manufacturing an LED package according to another exemplary embodiment. As shown in FIG. 2, a semi-finished LED package 100′ depicted in FIG. 1A is provided. In other words, a plurality of LED chips 120 are disposed on a first surface 112 of a lead frame 110, and the LED chips 120 are disposed in a plurality of reflective cups 130. The LED chips 120 are electrically connected to the lead frame 110. Besides, a packaging process is implemented to package the semi-finished LED package 100′ into a package housing 260, and the package housing 260 has a plurality of holes 262 respectively exposing the heat dissipation areas 116 on a second surface 114 of the lead frame 110. It should be mentioned that components in FIG. 1A are horizontally turned upside down in FIG. 2 in order to clearly describe the manufacturing steps of the exemplary embodiment. Same reference numbers in FIG. 1A and FIG. 2 represent the same components.

According to this exemplary embodiment, the thermal conductive material 250′ is directly disposed in the holes 262 of the package housing 260 after the packaging process is performed. A solidification process is performed to fill the holes 262 with the solidified thermal conductive material 250′. In this exemplary embodiment, the thermal conductive material 250′ can be any material described in the previous exemplary embodiment. The solidification process, as described in the above exemplary embodiment, can either include the heating and the cooling processes or merely include the cooling process. It should be mentioned that the manufacturing condition on which the heating process is performed in this exemplary embodiment can also be the same as that described in the previous exemplary embodiment. That is to say, in this exemplary embodiment, the temperature at which the solidification process is performed can be at most 180° C., so as to prevent the LED chips 120 from being damaged by high temperature. Accordingly, favorable manufacturing yield can also be achieved in this exemplary embodiment.

Specifically, in this exemplary embodiment, the thermal conductive material 250′ is disposed in the heat dissipation areas 116 of the lead frame 110 to form the heat dissipation blocks (not shown) after the packaging process is performed, which is different from the teachings of the previous embodiment, indicating the heat dissipation blocks are formed prior to the packaging process. The thermal conductive material 250′ can be solder paste, silver adhesive, metal powder, or liquid metal. Therefore, the thermal conductive material 250′ can be directly injected into each of the heat dissipation areas 116, or each of the heat dissipation areas 116 can be directly coated by the thermal conductive material 250′. Namely, the manufacturing process is relatively easy according to the exemplary embodiment. In addition, no additional fixture is required for forming the heat dissipation blocks in this exemplary embodiment, thus reducing the number of necessary equipment in the manufacturing process. However, according to an exemplary embodiment, the thermal conductive material 250′ can also be disposed in the heat dissipation areas 116 by screen printing the thermal conductive material 250′ into each of the heat dissipation areas 116.

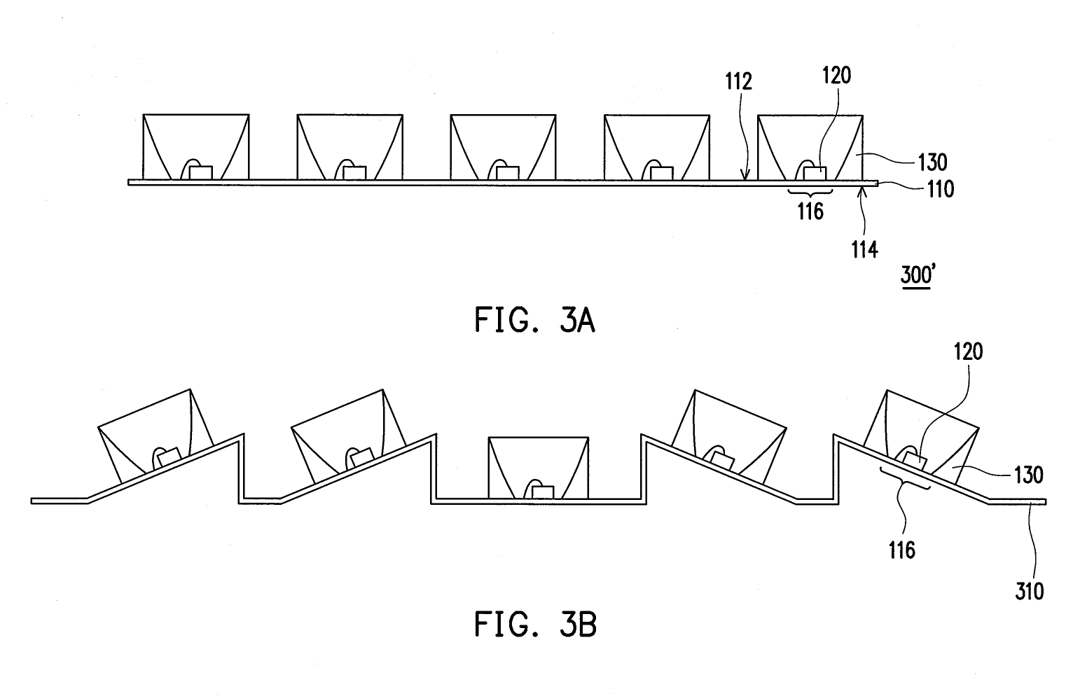

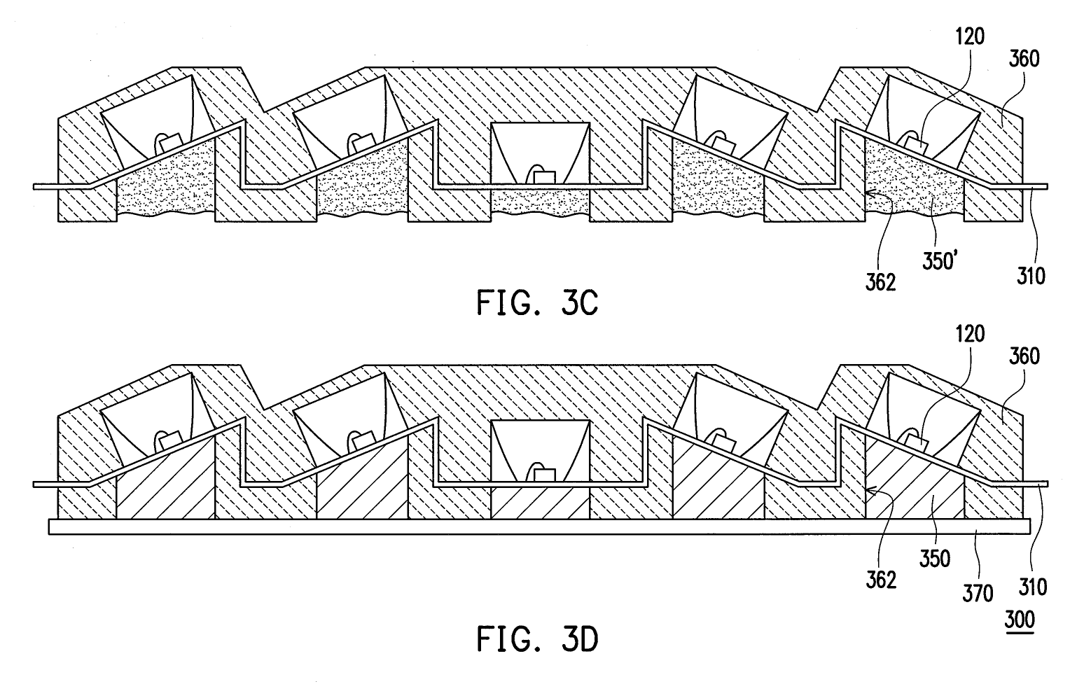

As described above, the thermal conductive material 250′ does not have specific shape but can change shape according to different fixtures or package housings. Accordingly, the method of manufacturing the LED package in this disclosure is conducive to application of the heat dissipation blocks to various LED packages having different designs. For instance, please refer to FIG. 3A to FIG. 3D. FIG. 3A to FIG. 3D are schematic views illustrating a method of manufacturing an LED package according to yet another exemplary embodiment. In FIG. 3A, a semi-finished LED package 300′ is provided. Components and relationship among the components of the semi-finished LED package 300′ are the same as those described in the previous exemplary embodiment shown in FIG. 1A, for instance. In other words, a plurality of LED chips 120 are disposed on a first surface 112 of a lead frame 110, and the LED chips 120 are disposed in a plurality of reflective cups 130. The LED chips 120 are electrically connected to the lead frame 110. As shown in FIG. 3A and FIG. 3B, a punching process is performed, such that the lead frame 110 becomes a three-dimensional lead frame 310.

With reference to FIG. 3C, a packaging process is implemented to package the LED chips 120 and the reflective cups 130 into a package housing 360, and the package housing 360 has a plurality of holes 362 respectively exposing the heat dissipation areas 116 on the lead frame 310. Note that the three-dimensional lead frame 310 is not planar, and therefore shapes of the holes 362 are not consistent.

Conventionally, when the heat dissipation blocks or thermal conductive blocks in fixed shape are disposed in the holes with different shapes, the incompatible shapes may lead to unfavorable heat dissipation or unsatisfactory heat conductivity. Hence, the heat dissipation blocks or the thermal conductive blocks in different shapes are customized based on the design of the lead frame according to the related art, which increases manufacturing costs. Moreover, the step of disposing the heat dissipation blocks or the thermal conductive blocks in different holes also complicates the entire process. Thus, high efficiency cannot be achieved in the conventional manufacturing process.

By contrast, in this exemplary embodiment, the thermal conductive material 350′ can be directly disposed in the holes 362. Since the thermal conductive material 350′ does not have specific shape, the holes 362 with different shapes can all be filled with the thermal conductive material 350′. In FIG. 3D, a solidification process is then performed to form the heat dissipation blocks 350 in the holes 362 with different shapes, and thereby the LED package 300 is formed. Shapes of the heat dissipation blocks 350 are approximately identical to those of the holes 362. In brief, the heat dissipation blocks 350 of this exemplary embodiment can be individually shaped based on the shapes of the holes 362. In comparison with the manufacturing method of the related art, the manufacturing method of this exemplary embodiment is relatively simple because it is not necessary to customize various heat dissipation blocks 350 in line with the shape change of the holes 362. Hence, in this exemplary embodiment, the manufacturing process is simplified, and the costs are lowered down.

Specifically, in this exemplary embodiment, the thermal conductive material 350′ can be the solder paste, the solder bar, the silver adhesive, the metal powder, or the liquid metal mentioned in the previous exemplary embodiment. Certainly, the manufacturing condition on which the solidification process is performed in this exemplary embodiment can also be the same as that described in the previous exemplary embodiment. That is to say, in this exemplary embodiment, the temperature at which the solidification process is performed can be at most 180° C., so as to prevent the LED chips 120 from being damaged by high temperature. Specifically, in order to increase the heat dissipation efficiency, a reflow process can be performed after the heat dissipation blocks 350 are formed according to the exemplary embodiment, and the three-dimensional lead frame 310 is connected to a heat dissipation substrate 370 through the heat dissipation blocks 350. Note that a plurality of LED chips are simultaneously disposed on the lead frame in the previous exemplary embodiments. However, in other exemplary embodiments, it is possible to dispose one LED chip on the lead frame, and the LED package characterized by favorable heat dissipation efficiency can still be formed by performing the simple manufacturing process as stated above.

In light of the foregoing, the heat dissipation blocks in this disclosure are directly formed on the lead frame by performing the solidification process. The shapes of the heat dissipation blocks can be changed together with different structural design. Moreover, in the method of manufacturing the LED package as provided in this disclosure, the heat dissipation blocks are formed by injecting the fluid thermal conductive material into the heat dissipation areas or by coating the heat dissipation areas with the powder thermal conductive material. As a result, the thermal conductive material in this disclosure can be easily disposed in the heat dissipation areas, so as to improve the manufacturing efficiency. On the other hand, the temperature at which the solidification process is performed for forming the heat dissipation blocks is within a certain range, e.g. at most 180° C., such that operating performance of the LED chips is not negatively affected by the temperature at which the solidification process is performed. As a result, the LED package provided in this disclosure can be characterized by great quality.

Although the disclosure has been described with reference to the above embodiments, it will be apparent to one of the ordinary skill in the art that modifications to the described exemplary embodiments may be made without departing from the spirit of the disclosure. Accordingly, the scope of the disclosure will be defined by the attached claims not by the above detailed descriptions.

What is claimed is:

1. A method of manufacturing a light emitting diode package, comprising:
disposing at least one light emitting diode chip on a first surface of a lead frame, wherein the at least one light emitting diode chip is connected to the lead frame, at least one heat dissipation area is defined on a second surface of the lead frame, the second surface is opposite to the first surface, and the at least one heat dissipation area corresponds to the at least one light emitting diode chip;
disposing a thermal conductive material in the at least one heat dissipation area; and
performing a solidification process to solidify the thermal conductive material and form at least one heat dissipation block directly coming into contact with the lead frame.

2. The method of manufacturing the light emitting diode package as claimed in claim 1, wherein a method of disposing the thermal conductive material in the at least one heat dissipation area comprises:
placing a fixture on the second surface of the lead frame, the fixture having at least one hole exposing the at least one heat dissipation area; and
filling the at least one hole with the thermal conductive material.

3. The method of manufacturing the light emitting diode package as claimed in claim 2, further comprising removing the fixture after the solidification process is performed to form the at least one heat dissipation block.

4. The method of manufacturing the light emitting diode package as claimed in claim 1, further comprising packaging the at least one light emitting diode chip and the lead frame into a package housing before disposing the thermal conductive material in the at least one heat dissipation area, the package housing having at least one hole exposing the at least one heat dissipation area on the lead frame.

5. The method of manufacturing the light emitting diode package as claimed in claim 4, wherein a method of disposing the thermal conductive material in the at least one heat dissipation area comprises directly disposing the thermal conductive material in the at least one hole of the package housing.

6. The method of manufacturing the light emitting diode package as claimed in claim 1, wherein a method of disposing the thermal conductive material in the at least one heat dissipation area comprises screen printing the thermal conductive material into the at least one heat dissipation area.

7. The method of manufacturing the light emitting diode package as claimed in claim 1, further comprising packaging the at least one light emitting diode chip and the lead frame into a package housing after forming the at least one heat dissipation block, the package housing exposing a side of the at least one heat dissipation block, the side of the at least one heat dissipation block being away from the lead frame.

8. The method of manufacturing the light emitting diode package as claimed in claim 1, further comprising performing a wire bonding process to electrically connect the at least one light emitting diode chip to the lead frame.

9. The method of manufacturing the light emitting diode package as claimed in claim 1, wherein the thermal conductive material comprises solder paste, solder bar, silver adhesive, metal powder, or liquid metal.

10. The method of manufacturing the light emitting diode package as claimed in claim 1, further comprising performing a punching process before disposing the thermal conductive material into the at least one heat dissipation block, such that the lead frame is a three-dimensional lead frame.

11. The method of manufacturing the light emitting diode package as claimed in claim 1, further comprising connecting the lead frame to a heat dissipation substrate through the at least one heat dissipation block.

12. The method of manufacturing the light emitting diode package as claimed in claim 11, wherein the at least one heat dissipation block and the heat dissipation substrate are connected by performing a reflow process.

13. The method of manufacturing the light emitting diode package as claimed in claim 1, further comprising packaging the at least one light emitting diode chip into at least one reflective cup when the at least one light emitting diode chip is disposed on the first surface of the lead frame.

14. The method of manufacturing the light emitting diode package as claimed in claim 1, wherein the thermal conductive material directly comes into contact with the lead frame, and a thermal conductive coefficient of the thermal conductive material is substantially greater than 10 W/m-K.

15. The method of manufacturing the light emitting diode package as claimed in claim 1, wherein the solidification process comprises performing a cooling process to solidify the thermal conductive material and form the at least one heat dissipation block.

16. The method of manufacturing the light emitting diode package as claimed in claim 15, wherein the solidification process further comprises performing a heating process before performing the cooling process to fluidify the thermal conductive material and solidifying the thermal conductive material and forming the at least one heat dissipation block in the cooling process.
